(19) United States
(12) Patent Application Publication
(10) Pub. No.: US 2026/0136508 A1
(43) Pub. Date: May 14, 2026

(54) COOLING APPARATUS FOR POWER MODULE AND INVERTER INCLUDING SAME

(71) Applicants: HYUNDAI MOTOR COMPANY, Seoul (KR); KIA CORPORATION, Seoul (KR)

(72) Inventors: Won Seok Lee, Hwaseong-si (KR); Kwang Min Choi, Hwaseong-si (KR); Chon Ok Kim, Hwaseong-si (KR); Baek Yu Kim, Hwaseong-si (KR); Chul Min Ahn, Hwaseong-si (KR); Sung Gon Byun, Hwaseong-si (KR); Jun Young Ha, Hwaseong-si (KR); Su Hyeon Maeng, Hwaseong-si (KR); Dong Hui Cheon, Hwaseong-si (KR); Ji Eun Kim, Hwaseong-si (KR); Yo Han Kim, Hwaseong-si (KR); Jae Hyuk Seo, Hwaseong-si (KR); Jong Ho Jung, Hwaseong-si (KR); Jong Yun Park, Hwaseong-si (KR); Sun Sung Kwon, Hwaseong-si (KR); Yun Kyung Ji, Hwaseong-si (KR)

(73) Assignees: HYUNDAI MOTOR COMPANY, Seoul (KR); KIA CORPORATION, Seoul (KR)

(21) Appl. No.: 19/207,843

(22) Filed: May 14, 2025

(30) Foreign Application Priority Data
Nov. 12, 2024 (KR) 10-2024-0159977

(51) Int. Cl. H05K 7/20

(52) U.S. Cl. CPC H05K 7/209

(57) ABSTRACT

A cooling apparatus for a power module is provided. The cooling apparatus includes a first surface contact cooler contacting one surface of the power module and including a first heat sink, in which a first air flow path is formed and a second surface contact cooler contacting the other surface of the power module and including a second heat sink, in which a second air flow path is formed, wherein the first air path and the second air path mutually form a continuous air movement path.

### CROSS-REFERENCE TO RELATED APPLICATION(S)

This application claims the benefit of priority to Korean Patent Application No. 10-2024-0159977 filed on Nov. 12, 2024, in the Korean Intellectual Property Office, the disclosure of which is incorporated herein by reference in its entirety.

### TECHNICAL FIELD

The present disclosure relates to a cooling apparatus for a power module and an inverter including the same.

### BACKGROUND

A power conversion device of an automobile receives direct current (DC) from a high-voltage battery, converts the received DC current into alternating current (AC), and supplies the same to a motor, and the torque and a rotational speed of the motor are controlled by adjusting the magnitude and phase of the AC current. A power module of the power conversion device is a switching element converting DC current received from the high-voltage battery into AC current, and heat is generated during the switching process, and damage may occur when the temperature rises above a certain level. Therefore, the power module of all power conversion devices uses cooling, and as the cooling performance is improved, the current with higher specifications may be converted in the power module, so the performance of the power conversion device is also improved. In some power conversion devices, the power module is cooled by forming a cooling flow path inside a housing or assembling of the power module with a separate cooler. A water-cooled cooler or an oil-cooled cooler is used as the cooler. However, in the case of using the water-cooled cooler or the oil-cooled cooler, components, such as a pump, radiator, pipe, and hose have to be used, which increases the manufacturing cost. Therefore, research on a cooling apparatus that may effectively perform cooling while reducing the manufacturing cost of a power module may be useful.

### SUMMARY

An aspect of the present disclosure is to provide a cooling apparatus for a power module that reduces manufacturing costs and provides improved cooling efficiency and provides for miniaturization and an inverter including the same.

According to an aspect of the present disclosure, a cooling apparatus for a power module includes a first surface contact cooler contacting one surface of the power module and including a first heat sink, in which a first air flow path is formed,, and a second surface contact cooler contacting the other surface of the power module and including a second heat sink, in which a second air flow path is formed, wherein the first air path and the second air path mutually form a continuous air movement path.

The second heat sink may be disposed on both longitudinal sides of the first heat sink.

The first surface contact cooler may include a first heat spreader contacting one surface of the power module, and the first heat sink may protrude from the first heat spreader.

The first heat spreader may include a first flat plate contact part having one surface in contact with one surface of the power module, and an extension part bent outwardly from one end portion of the first flat plate contact part in a width direction.

The first heat sink may include a horizontal heat sink protruding from the other surface of the first flat plate contact part in a horizontal direction, and a vertical heat sink protruding from a surface of the extension part not facing the horizontal heat sink in a vertical direction, wherein the first air flow path includes a horizontal air flow path formed in the horizontal heat sink and a vertical air flow path formed in the vertical heat sink.

The horizontal air flow path and the vertical air flow path may be formed parallel.

At least a portion of the second heat sink may be disposed to face the horizontal heat sink in a length direction so that the horizontal air flow path and the second air flow path form a continuous air movement path, and the other portion of the second heat sink may be disposed to face the vertical heat sink in the length direction so that the vertical air flow path and the second air flow path form a continuous air movement path.

The second surface contact cooler may include a second heat spreader having one surface in contact with the other surface of the power module, and the second heat sink may protrude in a direction in which the first heat sink is provided from both longitudinal sides of the second heat spreader.

The second heat sink may be disposed on both longitudinal sides of the first heat sink, and the first air flow path and the second air flow path may be provided continuously in the length direction of the first heat sink.

According to another aspect of the present disclosure, a cooling apparatus for a power module includes a first surface contact cooler contacting one surface of a power module and including a first heat sink, in which a first air flow path is formed, a second surface contact cooler disposed on both longitudinal sides of the first heat sink and including a second heat sink, in which a second air flow path is formed, the second surface contact cooler contacting the other surface of the power module, a case provided to surround at least a portion of an external surface of the first heat sink and the second heat sink, a center bracket provided between the first surface contact cooler and the second surface contact cooler and providing a space in which the power module is disposed, and a support holder coupled to the center bracket and pressing and fixing a surface of the second surface contact cooler not contacting the power module, wherein the first air flow path and the second air flow path mutually form a continuous air movement path.

The center bracket may block a portion of the second heat sink not facing the first heat sink in a length direction to prevent air movement to the power module.

The center bracket may include a bracket panel having one surface in contact with the first surface contact cooler, and a partition rib provided in plural on the other surface of the bracket panel in the length direction and forming a power module arrangement space in which the power module is disposed.

At least a portion of one surface of the partition rib may be in contact with the first surface contact cooler, and at least a portion of the other surface of the partition rib may be in contact with the second surface contact cooler.

The other surface of the partition rib may be provided with an insertion recess into which the second surface contact cooler is inserted.

Both longitudinal end portions of the case may be open, so that the second heat sink may be exposed to the both longitudinal sides of the case.

The case may include a side case part disposed on one surface of the first surface contact cooler and the second surface contact cooler in a width direction, an upper case part bent from one end of the side case part in a thickness direction, and a lower case part bent from the other end of the side case part in the thickness direction.

An internal surface of the side case part may be provided with a case spacer protruding toward the first surface contact cooler.

An end portion of the upper case part and an end portion of the lower case part may be coupled to one surface of the center bracket, and both end portions of the support holder may be coupled to the other surface of the center bracket.

The first surface contact cooler may include a first heat spreader contacting one surface of the power module, and the first heat sink may protrude from the first heat spreader.

The first heat spreader may include a first flat plate contact part having one surface contacting one surface of the power module, and an extension part bent outwardly from one end portion of the first flat plate contact part in a width direction, and the first heat sink may include a horizontal heat sink protruding from the other surface of the first flat plate contact part in a horizontal direction, and a vertical heat sink protruding from one surface of the extension part not facing the horizontal heat sink in a vertical direction.

At least a portion of the second heat sink may be disposed to face the horizontal heat sink in the length direction, and the other portion of the second heat sink may be disposed to face the vertical heat sink in the length direction.

The second surface contact cooler may include a second heat spreader having one surface in contact with the other surface of the power module, and the second heat sink may protrude in a direction in which the first heat sink is provided from both longitudinal sides of the second heat spreader.

According to another aspect of the present disclosure, an inverter includes a power module, a first surface contact cooler contacting one surface of the power module and including a first heat sink, in which a first air flow path is formed, and a second surface contact cooler including a second heat sink disposed on both longitudinal sides of the first heat sink, a second air flow path being formed in the second heat sink, and the second surface contact cooler contacting the other surface of the power module.

The power module may include a first substrate having one surface exposed externally, a second substrate having one surface exposed externally, and a chip mounted on the first substrate and disposed between the first substrate and the second substrate.

The first surface contact cooler may be in contact with an externally exposed surface of the first substrate on which the chip is mounted, and the second surface contact cooler may be in contact with an externally exposed surface of the second substrate on which the chip is not mounted.

The inverter may further include a case provided to surround at least a portion of an external surface of the first heat sink and the second heat sink, a center bracket provided between the first surface contact cooler and the second surface contact cooler and providing a space in which the power module is disposed, and a support holder coupled to the center bracket to press and fix a surface of the second surface contact cooler not contacting the power module.

The power module may be limited in longitudinal movement by the center bracket and limited in widthwise movement by the first surface contact cooler and the second surface contact cooler.

### BRIEF DESCRIPTION OF DRAWINGS

The above and other aspects, features, and advantages of the present disclosure may be understood from the following detailed description, taken in conjunction with the accompanying drawings.

FIG. 1 is a schematic perspective view illustrating an inverter connected to a blower according to an embodiment of the present disclosure.

FIG. 2 is a schematic cross-sectional view of a power module coupled to a cooling apparatus for a power module according to an embodiment of the present disclosure.

FIG. 3 is a front perspective view of a cooling apparatus for a power module according to an embodiment of the present disclosure.

FIG. 4 is a rear perspective view of a cooling apparatus for a power module according to an embodiment of the present disclosure.

FIG. 5 is a front exploded perspective view of a cooling apparatus for a power module according to an embodiment of the present disclosure.

FIG. 6 is a rear exploded perspective view of a cooling apparatus for a power module according to an embodiment of the present disclosure.

FIG. 7 is a cross-sectional view taken along line I-I′ of FIG. 3.

FIG. 8 is a cross-sectional view taken along line II-II′ of FIG. 3.

FIG. 9 is a cross-sectional view taken along line III-III′ of FIG. 3.

### DETAILED DESCRIPTION

While the present disclosure may be modified in various ways and take on various alternative forms, specific embodiments thereof are shown in the drawings and described in detail below. However, there is no intent to limit the present disclosure to the particular forms disclosed, but on the contrary, the present disclosure is intended to cover modifications, equivalents, and alternatives falling within the spirit and scope of the present disclosure.

It may be understood that, although the terms “first,” “second,” and/or the like may be used herein to describe various elements, these elements may not be limited by these terms. These terms are used to distinguish one element from another. For example, a first element could be termed a second element, and a second element could similarly be termed a first element without departing from the scope of the present disclosure. As used herein, the term “and/or” includes any and all combinations of one or more of the associated listed items.

The terms, such as “unit,” “part,” “portion,” and/or the like may be used to describe various components, but the components may not be limited by these terms. The above terms may refer to physically/visually distinct components, and also to functions or components of a portion even if the corresponding portion is not clearly divided.

The terms used herein to describe embodiments of the present disclosure is not intended to limit the scope of the present disclosure. The articles “a” and “an” are singular in that they have a single referent, however the use of the singular form in the present document may not preclude the presence of more than one referent. In other words, elements of the present disclosure referred to in the singular may number one or more, unless the context clearly indicates otherwise. It may be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein including technical and scientific terms have the same meanings as understood by those skilled in the art to which the present disclosure pertains. Such terms as provided in generally used dictionaries may be construed to have the same meanings as those of the contexts of the related art, and unless provided in the application, they may not be construed to have (e.g., ideally or excessively) formal meanings.

In the description herein, terms used in relation to directions are described based on the illustration in the drawings. Hereinafter, embodiments of the present disclosure may be described with reference to the accompanying drawings.

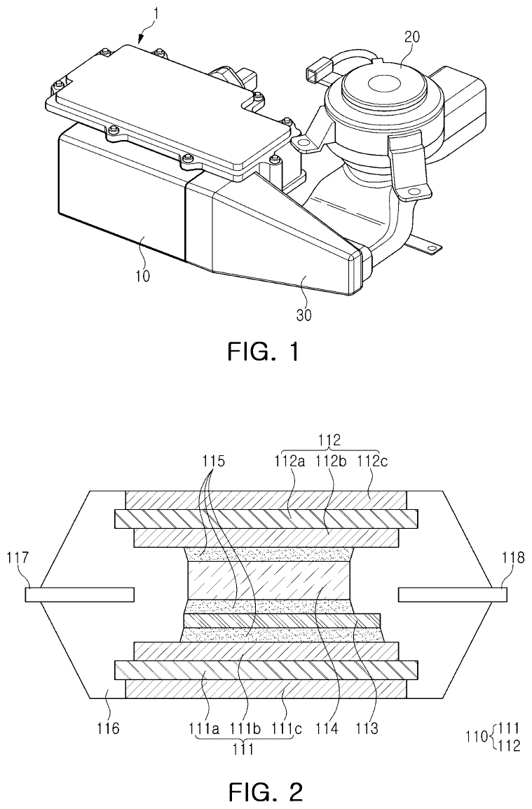

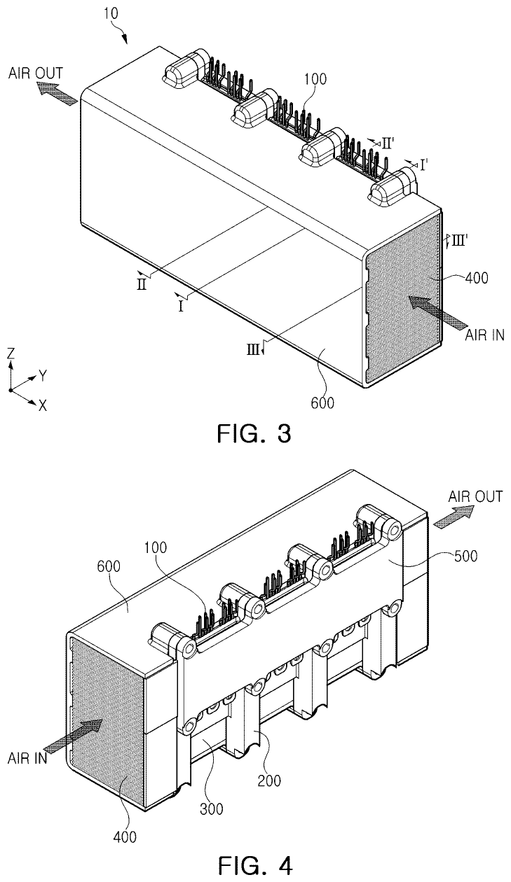

FIG. 1 is a schematic perspective view illustrating an inverter connected to a blower according to an embodiment of the present disclosure, FIG. 2 is a schematic cross-sectional view of a power module provided in an inverter according to an embodiment of the present disclosure, FIG. 3 is a front perspective view of a cooling apparatus for a power module according to an embodiment of the present disclosure, and FIG. 4 is a rear perspective view of a cooling apparatus for a power module according to an embodiment of the present disclosure.

Referring to FIGS. 1 to 4, an inverter 1 according to an embodiment of the present disclosure may include a power module 100 and a cooling apparatus 10 for a power module. The inverter 1 is a device inverting direct current (DC) into alternating current (AC) and may serve to drive an electric motor upon receiving power from a high-voltage battery. The inverter 1 may be connected to a blower 20. The blower 20 may provide (e.g., spray) air to the cooling apparatus 10 for a power module of the inverter 1. The power module 100 may be cooled by heat exchange between the air supplied through the blower 20 and the cooling apparatus 10 for a power module. The inverter 1 may be connected to the blower 20 through at least one duct 30. The duct 30 may guide air flow generated by the blower 20 to the inverter 1.

The power module 100 may process high voltage and current to perform power conversion. The power module 100 may be classified into a single-sided cooling power module in which a cooler is connected to a (e.g., one or first) side of the power module and a double-sided cooling power module in which a cooler is connected to both sides, depending on a cooling method. In the inverter 1 according to an embodiment of the present disclosure, the power module 100 may be the single-sided cooling power module and the double-sided cooling power module. However, hereinafter, a case in which the power module 100 is provided as the double-sided cooling power module is described as an example.

Referring to FIG. 2, the power module 100 may include a substrate 110 and a chip 113. The substrate 110 may include a first substrate 111 and a second substrate 112. The first substrate 111 may include a first insulating layer 111a, a first internal metal layer 111b provided on an upper surface of the first insulating layer 111a, and a first external metal layer 111c provided on a lower surface of the first insulating layer 111a. The second substrate 112 may include a second insulating layer 112a, a second internal metal layer 112b provided on a lower surface of the second insulating layer 112a, and a second external metal layer 112c provided on an upper surface of the second insulating substrate 112a.

The second substrate 112 may be disposed above the first substrate 111. A spacer 114 may be provided between the second substrate 112 and the first substrate 111 for electrical/physical connection between the second substrate 112 and the first substrate 111. The spacer 114 may separate the first substrate 111 and the second substrate 112 and electrically connect the first substrate 111 and the second substrate 112.

The chip 113 may be disposed between the first substrate 111 and the second substrate 112. The chip 113 may be mounted on the first substrate 111. When the chip 113 is mounted on the first substrate 111, (e.g., relatively) more heat may be transferred to the first substrate 111 than to the second substrate 112 when the power module 100 operates. The chip 113 may be electrically connected to at least one of the first internal metal layer 111b or the second internal metal layer 112b. The substrate 110, the chip 113, and the spacer 114 may be soldered. A solder layer 115 may be provided between the substrate 110, the chip 113, and the spacer 114.

The chip 113 may include, for example, at least one of an insulated gate bipolar transistor (IGBT), a compound semiconductor (SIC), a shunt circuit, a silicon controlled rectifier (SCR), a power transistor, a MOS transistor, a power rectifier, a power regulator, or a diode.

At least a portion of the first external metal layer 111c and the second external metal layer 112c may be exposed to the outside of a molded portion 116. One (e.g., a) surface of the first external metal layer 111c and the second external metal layer 112c exposed to the outside of the molded portion 116 may contact the cooling apparatus 10 for a power module, as described herein. The power module 100 may include a signal lead 117 for transmitting a control signal and a power lead 118 for transmitting power.

Referring to FIGS. 3 and 4, the power module 100 may be disposed inside the cooling apparatus 10 for a power module. Here, the power module 100 may contact the cooling apparatus 10 for a power module. For example, both surfaces of the power module 100 from which the first external metal layer 111c and the second external metal layer 112c of the power module 100 are exposed externally may contact the cooling apparatus 10 for a power module.

The cooling apparatus 10 for a power module may cool the power module 100 when the inverter 1 operates. For example, the cooling apparatus 10 for a power module may cool the power module 100 by receiving heat generated by the power module 100 and exchanging heat with air supplied through the blower 20 and the duct 30. The air supplied through the blower 20 and the duct 30 may be introduced to a (e.g., one or first) longitudinal side of the cooling apparatus 10 for a power module and then discharged to the other (e.g., another or second) longitudinal side thereof. Here, the terms for directions are provided such that a length direction refers to an X-axis direction based on FIG. 3, a width direction refers to a Y-axis direction based on FIG. 3, and a thickness direction refers to a Z-axis direction based on FIG. 3.

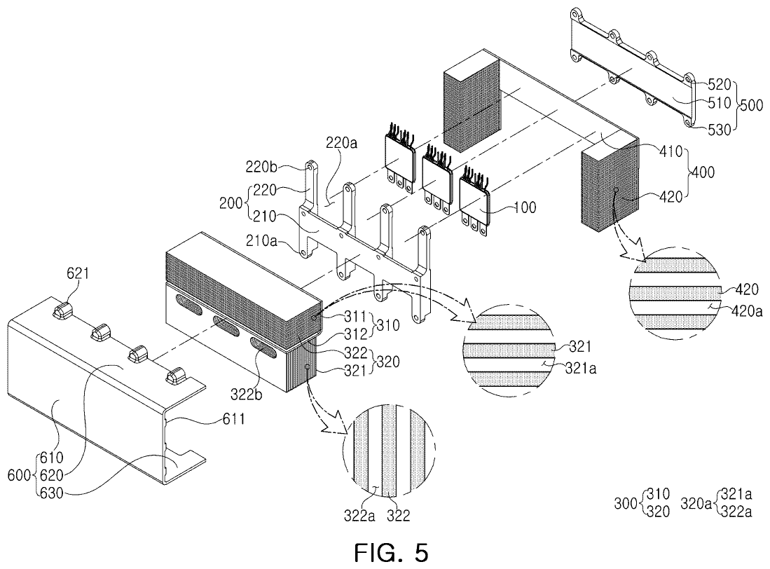

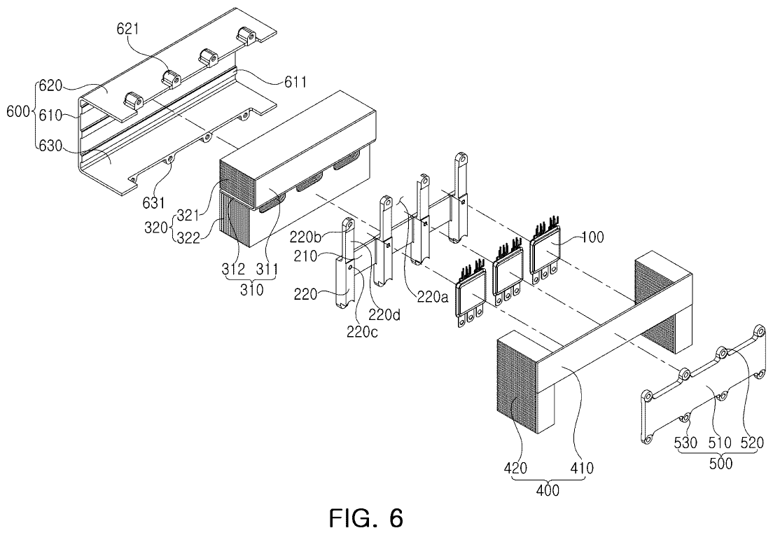

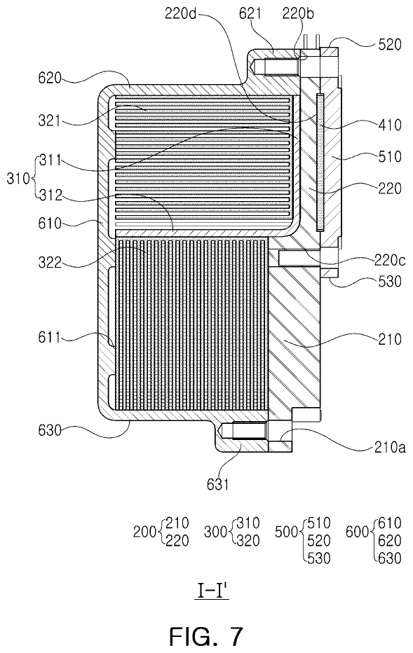

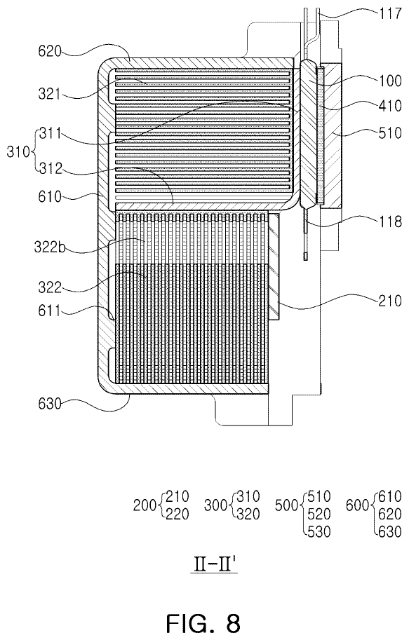

FIG. 5 is a front exploded perspective view of a cooling apparatus for a power module according to an embodiment of the present disclosure, FIG. 6 is a rear exploded perspective view of a cooling apparatus for a power module according to an embodiment of the present disclosure, FIG. 7 is a cross-sectional view taken along line I-I′ of FIG. 3, and FIG. 8 is a cross-sectional view taken along line II-II′ of FIG. 3.

Referring to FIGS. 5 to 8, the cooling apparatus 10 for a power module according to an embodiment of the present disclosure may include a first surface contact cooler 300, a second surface contact cooler 400, a case 600, a center bracket 200, and a support holder 500.

The first surface contact cooler 300 may be in contact with one (e.g., a) surface of the power module 100. The first surface contact cooler 300 may be in contact with at least one of the first substrate 111 and the second substrate 112 of the power module 100 having a (e.g., relatively) large amount of heat generation. For example, the first surface contact cooler 300 may be in contact with the first substrate 111 on which the chip 13 of the power module 100 is mounted.

The first surface contact cooler 300 may include, for example, a first heat spreader 310 in contact with one (e.g., a) surface of the power module 100 and a first heat sink 320 protruding from the first heat spreader 310.

The first heat spreader 310 may be in direct contact with one (e.g., a) surface of the power module 100. The first heat spreader 310 may transfer heat received from the power module 100 to the first heat sink 320.

The first heat spreader 310 may be in contact with the first external metal layer 111c of the first substrate 111. The first heat spreader 310 may include, for example, a first flat plate contact part 311 having one (e.g., a) surface in contact with one (e.g., a) surface of the power module 100 and an extension part 312 bent outwardly in the width direction from one (e.g., an) end portion of the first flat plate contact part 311. The first heat spreader 310 may be provided in an overall ‘L’ shape.

The first heat sink 320 may protrude from the first heat spreader 310. The first heat sink 320 may receive heat from the first heat spreader 310 and exchange heat with air passing through a first air flow path 320a. The first heat sink 320 may be provided in a shape in which a plurality of fins are connected. The first air flow path 320a may be formed between the plurality of fins. The first air flow path 320a may refer to a passage through which air introduced through the blower 20 and the duct 30 flows. The air introduced through the blower 20 and the duct 30, while flowing along the first air flow path 320a, exchange heat with the first heat sink 320 to absorb heat from the first heat sink 320.

The first heat sink 320 may include, for example, a horizontal heat sink 321 protruding from the other (e.g., another) surface of the first flat plate contact part 311 in a horizontal direction and a vertical heat sink 322 protruding from one (e.g., a) surface not facing the horizontal heat sink 321 of the extension part 312 in a vertical direction. A horizontal air flow path 321a may be formed in the horizontal heat sink 321. A vertical air flow path 322a may be formed in the vertical heat sink 322. The first air flow path 320a may include the horizontal air flow path 321a and the vertical air flow path 322a. The horizontal air flow path 321a and the vertical air flow path 322a may be formed in parallel. For example, the horizontal air flow path 321a may be formed in the length direction above the extension part 312, and the vertical air flow path 322a may be formed in the length direction below the extension part 312. The vertical heat sink 322 may include at least one through-hole 322b for smooth air flow and heat exchange. The through-hole 322b may be provided by penetrating through a plurality of fins constituting the vertical heat sink 322.

The second surface contact cooler 400 may be in contact with the other surface of the power module. The second surface contact cooler 400 may be in contact with at least one of the first substrate 111 and the second substrate 112 of the power module 100 having a (e.g., relatively) small amount of heat generation. For example, the second surface contact cooler 400 may be in contact with the second substrate 112 on which the chip 13 of the power module 100 is not mounted.

The second surface contact cooler 400 may include, for example, a second heat spreader 410 contacting the other surface of the power module 100 and a second heat sink 420 protruding from the second heat spreader 410.

The second heat spreader 410 may transfer heat received from the power module 100 to the second heat sink 420. The second heat spreader 410 may be provided in the shape of a panel extending in the length direction.

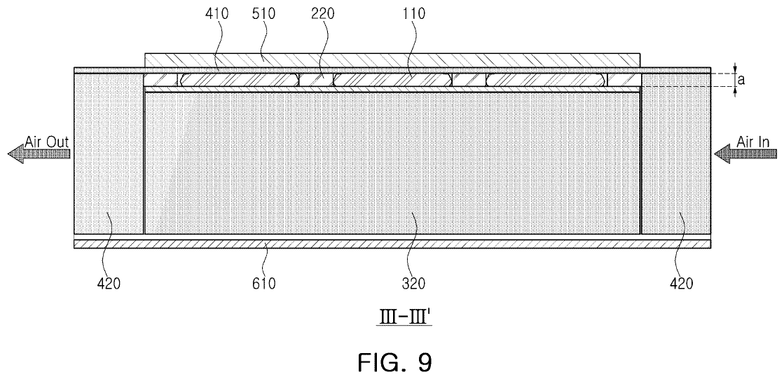

The second heat sink 420 may be provided in a shape in which a plurality of fins are connected, and a second air flow path 420a may be formed between the plurality of fins. The first air flow path 320a of the first heat sink 320 and the second air flow path 420a of the second heat sink 420 may form a continuous air movement path (see FIG. 9).

The second heat sink 420 may be provided on at least one of both longitudinal sides of the second heat spreader 410. Hereinafter, a case in which the second heat sink 420 is provided on both longitudinal sides of the second heat spreader 410 is provided as an example.

The second heat sink 420 may protrude from one longitudinal side of the second heat spreader 410 in a direction in which the first heat sink 320 is provided. The first heat sink 320 may be disposed on the longitudinal inner side of the second heat sink 420. In other words, the second heat sink 420 may be disposed on both longitudinal sides of the first heat sink 320, and the second heat sink 420 and the first heat sink 320 may overlap at least partly (e.g., partially) in the length direction. Accordingly, the first air flow path 320a of the first heat sink 320 and the second air flow path 420a of the second heat sink 420 may be provided in a longitudinally (e.g., continuous) manner. For example, at least a portion of the second heat sink 420 may be disposed to face the horizontal heat sink 321 in the length direction, so that the horizontal air flow path 321a and the second air flow path 420a may form a continuous air movement path. In addition, the other portion of the second heat sink 420 may be disposed to face the vertical heat sink 322 in the length direction, so that the vertical air flow path 322a and the second air flow path 420a may form a continuous air movement path.

The center bracket 200 may be provided between the first surface contact cooler 300 and the second surface contact cooler 400 to provide a space 220a in which the power module 100 is disposed. The front of the center bracket 200 may be provided with a shape corresponding to the rear of the first surface contact cooler 300. Accordingly, the front of the center bracket 200 may be in (e.g., close) contact with the rear of the first surface contact cooler 300. The center bracket 200 may include, for example, a bracket panel 210 and a partition rib 220.

The bracket panel 210 may be provided in a flat shape. One (e.g., a) surface of the bracket panel 210 may be in (e.g., close) contact with the vertical heat sink 322. A first fastening hole 210a for coupling with the case 600 may be provided at the bottom of the bracket panel 210. The partition rib 220 may be provided on the other (e.g., another) surface of the bracket panel 210.

A plurality of partition ribs 220 may be provided in the length direction on the other surface of the bracket panel 210. At least a portion of one (e.g., a) surface of the partition rib 220 may be in contact with the first surface contact cooler 300. At least a portion of the other (e.g., another) surface of the partition rib 220 may be in contact with the second surface contact cooler 400. The partition rib 220 may form a power module 100 arrangement space 220a. For example, the power module 100 may be disposed in the space 220a between the partition ribs 220 adjacent to each other. The power module 100 may be restricted from moving in the length direction by the partition rib 220 of the center bracket 200. The power module 100 may be restricted from moving in the width direction by the first surface contact cooler 300 and the second surface contact cooler 400.

An upper portion of the partition rib 220 may protrude upward from the bracket panel 210. A portion of the front surface of the bracket panel 210 protruding upward from the bracket panel 210 may be in (e.g., close) contact with the first heat spreader 310. A second fastening hole 220b for coupling with the case 600 and the support holder 500 may be provided at an upper end of the partition rib 220. In addition, a third fastening hole 220c for coupling with the support holder 500 may be provided in the partition rib 220. The third fastening hole 220c may be provided in a lower portion in the thickness direction at a provided (e.g., certain) distance from the second fastening hole 220b to correspond to the length of the support holder 500 in thickness direction. An insertion recess 220d may be provided on the other surface of the partition rib 220. The second surface contact cooler 400 may be inserted into the insertion recess 220d. For example, the second heat spreader 410 may be inserted into the insertion recess 220d. The second heat spreader 410 may be inserted into the insertion recess 220d to press and support the power module 100. A depth of the insertion recess 220d may be adjusted in accordance with the length of the power module 100 in the width direction.

Meanwhile, the center bracket 200 may provide the space 220a in which the power module 100 is disposed and may prevent air supplied through the blower 20 and the duct 30 from directly flowing to the power module 100. For example, the center bracket 200 may block a portion (a, see FIG. 9) of the second heat sink 420 not facing the first heat sink 320 in the length direction, thereby blocking air movement to the power module 100.

The case 600 may constitute a portion of the exterior of the cooling apparatus 10 for a power module. The case 600 may be provided to surround at least a portion of the first heat sink 320 and the second heat sink 420. Both longitudinal end portions of the case 600 may be open so that the second heat sink 420 may be exposed to both longitudinal sides of the case 600. The air supplied through the blower 20 and the duct 30 may be introduced through the second heat sink 420 exposed to one longitudinal side of the case 600, pass through the first heat sink 320, and be discharged through the second heat sink 420 exposed to the other longitudinal side of the case 600.

The case 600 may include, for example, a side case part 610 disposed on one (e.g., a) surface of the first surface contact cooler 300 and the second surface contact cooler 400 in the width direction, an upper case part 620 bent from one (e.g., an) end of the side case part 610 in the thickness direction, and a lower case part 630 bent from the other (e.g., another) end of the side case part 610 in the thickness direction. A case spacer 611 protruding toward the first surface contact cooler 300 may be provided on an internal surface of the side case part 610. The case spacer 611 may be provided to extend in the length direction from the internal surface of the side case part 610, and a plurality of case spacers may be provided in the thickness direction.

An upper case fastening portion 621 may be provided at an end portion of the upper case part 620. The upper case fastening portion 621 may be coupled to the center bracket 200. For example, a separate fastening member, such as a screw, may be coupled to the upper case fastening portion 621 by passing through the second fastening hole 220b of the center bracket 200, so that the upper case fastening portion 621 may be coupled to the center bracket 200. A lower case fastening portion 631 may be provided at an end portion of the lower case part 630. The lower case fastening portion 631 may be coupled to the center bracket 200. For example, a separate fastening member, such as a screw, may be coupled to the lower case fastening portion 631 by passing through the first fastening hole 210a of the center bracket 200, so that the lower case fastening portion 631 may be coupled to the center bracket 200.

The support holder 500 may press and fix the second surface contact cooler 400 and the power module 100. Both end portions of the support holder 500 in the thickness direction may be coupled to the center bracket 200. An upper support holder fastening portion 520 may be provided at an upper end portion of the support holder 500 in the thickness direction. The upper support holder fastening portion 520 may be coupled to the center bracket 200. For example, a separate fastening member, such as a screw, may be coupled to the upper case fastening portion 621 by passing through the upper support holder fastening portion 520 and the second fastening hole 220b, so that the upper support holder fastening portion 520 may be coupled to the center bracket 200. A lower support holder fastening portion 530 may be provided at a lower end portion of the support holder 500 in the thickness direction. The lower support holder fastening portion 520 may be coupled to the center bracket 200. For example, a separate fastening member, such as a screw, may be coupled to the third fastening hole 220c of the center bracket 200 by passing through the lower support holder fastening portion 520, so that the support holder fastening portion 520 may be connected to the center bracket 200.

The cooling apparatus for a power module according to an embodiment of the present disclosure forms a continuous air movement path by arranging the first heat sink 320 and the second heat sink 420 on one (e.g., a) surface of the power module 100, thereby providing an effect of miniaturization compared to some configurations in which cooling apparatuses are formed on both sides of the power module 100. In addition, an effect of reducing the manufacturing cost by omitting various components used to implement existing water-cooling methods or oil-cooling methods.

The cooling apparatus for a power module and the inverter according to an embodiment of the present disclosure to reduce the manufacturing cost.

In addition, the cooling apparatus for a power module and the inverter according to an embodiment of the present disclosure improves cooling efficiency.

In addition, the cooling apparatus for a power module and the inverter according to an embodiment of the present have an effect of miniaturization.

While embodiments have been shown and described above, it may be apparent to those skilled in the art that modifications and variations may be made without departing from the scope of the present disclosure as provided in the claims.

What is claimed is:

1. A cooling apparatus for a power module, the cooling apparatus comprising:
a first surface contact cooler contacting a first surface of the power module and including a first heat sink, in which a first air flow path is formed; and
a second surface contact cooler contacting a second surface of the power module and including a second heat sink, in which a second air flow path is formed,
wherein the first air flow path and the second air flow path mutually form a continuous air movement path.

2. The cooling apparatus of claim 1, wherein the second heat sink is disposed on longitudinal sides of the first heat sink.

3. The cooling apparatus of claim 1, wherein the first surface contact cooler includes a first heat spreader contacting a surface of the power module, and the first heat sink protrudes from the first heat spreader.

4. The cooling apparatus of claim 3, wherein
the first heat spreader includes:
a first flat plate contact part having a surface in contact with a surface of the power module; and
an extension part bent outwardly from an end portion of the first flat plate contact part in a width direction.

5. The cooling apparatus of claim 4, wherein
the first heat sink includes:
a horizontal heat sink protruding from another surface of the first flat plate contact part in a horizontal direction; and
a vertical heat sink protruding from a surface of the extension part not facing the horizontal heat sink in a vertical direction,
wherein the first air flow path includes a horizontal air flow path formed in the horizontal heat sink and a vertical air flow path formed in the vertical heat sink.

6. The cooling apparatus of claim 5, wherein
at least a portion of the second heat sink is disposed to face the horizontal heat sink in a length direction, wherein the horizontal air flow path and the second air flow path form a continuous air movement path, and
another portion of the second heat sink is disposed to face the vertical heat sink in the length direction, wherein the vertical air flow path and the second air flow path form a continuous air movement path.

7. The cooling apparatus of claim 1, wherein
the second surface contact cooler includes a second heat spreader having a surface in contact with the second surface of the power module, and
the second heat sink protrudes in a direction in which the first heat sink is provided from longitudinal sides of the second heat spreader.

8. The cooling apparatus of claim 7, wherein the second heat sink is disposed on longitudinal sides of the first heat sink, and the first air flow path and the second air flow path are provided continuously in a length direction of the first heat sink.

9. A cooling apparatus for a power module, the cooling apparatus comprising:
a first surface contact cooler contacting a first surface of a power module and including a first heat sink, in which a first air flow path is formed;
a second surface contact cooler disposed on longitudinal sides of the first heat sink and including a second heat sink, in which a second air flow path is formed, the second surface contact cooler contacting a second surface of the power module;
a case provided to surround at least a portion of an external surface of the first heat sink and the second heat sink;
a center bracket provided between the first surface contact cooler and the second surface contact cooler and providing a space in which the power module is disposed; and
a support holder coupled to the center bracket and pressing and fixing a surface of the second surface contact cooler not contacting the power module,
wherein the first air flow path and the second air flow path mutually form a continuous air movement path.

10. The cooling apparatus of claim 9, wherein the center bracket blocks a portion of the second heat sink not facing the first heat sink in a length direction to prevent air movement to the power module.

11. The cooling apparatus of claim 9, wherein
the center bracket includes:
a bracket panel having a surface in contact with the first surface contact cooler; and
a partition rib provided in plural on another surface of the bracket panel in a length direction and forming a power module arrangement space in which the power module is disposed.

12. The cooling apparatus of claim 11, wherein at least a portion of a first surface of the partition rib is in contact with the first surface contact cooler, and at least a portion of a second surface of the partition rib is in contact with the second surface contact cooler.

13. The cooling apparatus of claim 12, wherein the second surface of the partition rib is provided with an insertion recess into which the second surface contact cooler is inserted.

14. The cooling apparatus of claim 9, wherein longitudinal end portions of the case are open, so that the second heat sink is exposed to the longitudinal sides of the case.

15. The cooling apparatus of claim 9, wherein
the case includes:
a side case part disposed on a surface of the first surface contact cooler and the second surface contact cooler in a width direction;
an upper case part bent from an end of the side case part in a thickness direction; and
a lower case part bent from another end of the side case part in the thickness direction.

16. The cooling apparatus of claim 15, wherein an end portion of the upper case part and an end portion of the lower case part are coupled to a surface of the center bracket, and end portions of the support holder are coupled to another surface of the center bracket.

17. The cooling apparatus of claim 9, wherein the first surface contact cooler includes a first heat spreader contacting a surface of the power module, and the first heat sink protrudes from the first heat spreader.

18. The cooling apparatus of claim 17, wherein
the first heat spreader includes:
a first flat plate contact part having a surface contacting a surface of the power module; and
an extension part bent outwardly from an end portion of the first flat plate contact part in a width direction, and
the first heat sink includes:
a horizontal heat sink protruding from another surface of the first flat plate contact part in a horizontal direction; and
a vertical heat sink protruding from a surface of the extension part not facing the horizontal heat sink in a vertical direction.

19. The cooling apparatus of claim 18, wherein at least a portion of the second heat sink is disposed to face the horizontal heat sink in a length direction, and another portion of the second heat sink is disposed to face the vertical heat sink in the length direction.

20. The cooling apparatus of claim 9, wherein the second surface contact cooler includes a second heat spreader having a surface in contact with another surface of the power module, and the second heat sink protrudes in a direction in which the first heat sink is provided from longitudinal sides of the second heat spreader.
